(19) United States
(12) Patent Application Publication
(10) Pub. No.: US 2009/0039924 A1
(43) Pub. Date: Feb. 12, 2009

(54) Systems and methods for reducing distortion in semiconductor based sampling systems

(76) Inventors: Alfio Zanchi, Colorado Springs, CO (US); Randall V. Jack, Colorado Springs, CO (US); David Thomas, Colorado Springs, CO (US); Richard Reay, Mountain View, CA (US); Fwurong Marco Pan, Saratoga, CA (US)

Correspondence Address: MCDERMOTT WILL & EMERY LLP, 600 13TH STREET, N.W., WASHINGTON, DC, 20005-3096, US

(21) Appl. No.: 11/891,211

(22) Filed: Aug. 9, 2007

(51) Int. Cl. G11C 27/02

(52) U.S. Cl. 327/94

(57) ABSTRACT

Circuits and methods that improve the performance of electronic sampling systems are provided. Parasitic capacitance associated with bootstrap circuitry is reduced, thereby decreasing signal distortion caused by capacitive loading at the input of the sampling circuit. The impedance of a sampling semiconductor switch is maintained substantially constant during sample states, at least in part, by accounting for non-linear parasitic capacitances associated with a sampling switch control terminal in order to reduce or minimize signal distortion associated with sampled signals that pass through the sampling switch.

### BACKGROUND OF THE INVENTION

The present inventions relate to electronic sampling systems. More particularly, the inventions relate to circuits and methods that reduce signal distortions commonly associated with electronic implementations of sampling systems.

Sampling systems are widely used in electronics. For example, sampling systems are frequently found in popular consumer electronic devices such as MP3 players, DVD players and cellular telephones. Other common uses of sampling systems include those related to data acquisition, test and measurement, and control system applications. More specifically, sampling systems and sample-based technology may be found in the electronic components used to construct such devices, which include analog-to-digital converters, switched capacitor networks, signal acquisition circuitry, comparators, and others.

Sampling systems frequently employ sample and hold circuits that acquire a signal and maintain a representation of it in a storage device so that another circuit can measure or otherwise observe the acquired signal. However, as is known in the art, the mere act of sampling a signal of interest can cause a certain amount of distortion to be imparted to the sampled signal.

The signal distortion produced by components in the sampling circuitry tends to limit the useful magnitude or frequency range of an input signal. Such distortion may be caused by various factors such as the non-linear resistance characteristics of switches in the sample and hold circuits, effects associated with turnoff thresholds, bulk effect, switch ratio match variations, and process variations. Distortion may also be produced by, for example, parasitic capacitances of switches in sampling circuits, signal dependent charge injection by switches in the sampling circuits, non-linear load currents flowing through input source resistances.

Thus, in view of the foregoing, it would be desirable to provide circuitry and methods that improve the performance of electronic sampling systems by reducing signal distortions commonly associated with the physical implementations of such circuits.

### SUMMARY OF THE INVENTION

It is therefore an object of the present invention to provide circuits and methods that improve the performance of electronic sampling systems, by reducing signal distortions commonly associated with the physical implementations of such circuits.

These and other objects are accomplished in accordance with the principles of the present invention by providing circuitry and methods that reduce signal distortion in sampling systems. In one embodiment of the present invention a sampling circuit maintains the impedance of a sampling switch substantially independent of an input signal during a sample mode to reduce signal distortions associated with impedance variance or mismatch. Energy storage devices used to generate a boost voltage are coupled to a voltage source through switches rather than diodes to maximize the boost voltage and to reduce signal distortions associated with impedance variance due to parallel parasitic capacitance based on signal-dependent reverse bias voltage and charge re-distribution that occurs when transitioning from a sample state to a hold state. Moreover, the energy storage devices are assembled and sized such as, when coupled to the input node, will present a reduced additional parasitic capacitive load. The foregoing and other embodiments of the invention are described in more detail below.

### BRIEF DESCRIPTION OF THE DRAWINGS

The above and other objects and advantages of the present invention will be apparent upon consideration of the following detailed description, taken in conjunction with the accompanying drawings, in which like reference characters refer to like parts throughout, and in which:

FIGS. 1A and 1B illustrate charge redistribution among certain energy storage elements in a bootstrap circuit in accordance with the principles of the present invention;

FIG. 2 is a generalized schematic diagram of one embodiment of a sample and hold circuit constructed in accordance with the principles of the present invention;

FIG. 3 is a schematic diagram of another embodiment of a sample and hold circuit constructed in accordance with the principles of the present invention;

FIG. 4 is a more detailed schematic diagram of another embodiment of a sample and hold circuit constructed in accordance with the principles of the present invention;

FIG. 5 is a more detailed schematic diagram of another embodiment of a sample and hold circuit constructed in accordance with the principles of the present invention;

FIG. 6A is a more detailed schematic diagram of another embodiment of a sample and hold circuit constructed in accordance with the principles of the present invention;

FIG. 6B is a more detailed schematic diagram of another embodiment of a sample and hold circuit constructed in accordance with the principles of the present invention;

FIG. 7 is a more detailed schematic diagram of another embodiment of a sample and hold circuit constructed in accordance with the principles of the present invention; and

FIG. 8 is a more detailed schematic diagram of another embodiment of a sample and hold circuit constructed in accordance with the principles of the present invention.

### DETAILED DESCRIPTION OF THE INVENTION

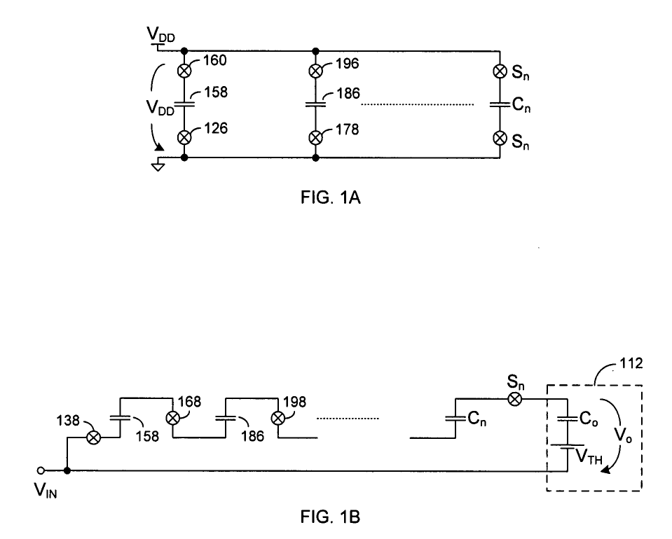

FIG. 1A is a general illustration of how charge storage devices may be configured in accordance with one embodiment of the present invention to reduce capacitive loading on an input terminal of a sampling system and to compensate for parasitic capacitance associated with a control terminal of a semiconductor sampling switch in order to increase the precision with which signals are sampled. As shown, the network of FIG. 1A includes bootstrap capacitors 158 and 186 which are charged by being coupled between one or more bias voltages V_{DD} and ground. This typically occurs when the sampling system is in a hold state (discussed in more detail below). Although only two capacitors and associated switches 126, 160, 178 and 196 are shown, it will be understood that additional ones may be added if desired. This is generally represented in FIG. 1A by switches S_{N} and capacitor C_{N}. Assuming the size C of each of the capacitors is substantially the same (although they may be different, if desired), each accumulates a charge quantity generally set forth below in equation (1):

Q=C*V_{DD}. (1)

Next, during a sample state, generally illustrated in FIG. 1B, charge storage devices such as bootstrap capacitors 158 and 186 may be coupled in series through switch 168. Input signal V_{IN} may also be coupled series with the bootstrap capacitors through switch 138. Again, although only two capacitors and associated switches are shown, it will be understood that additional ones may be added if desired. This is generally represented in FIG. 1B by switch S_{N} and capacitor C_{N}

In FIG. 1B load capacitor Co and voltage source Vth model, in a first order approximation, the control terminal of a semiconductor sampling switch 112. Capacitor Co represents the gate to channel capacitance present at the control terminal of such switch when the switch is in a conduction state (i.e. when it presents a low impedance between its terminals). A capacitance value Co is associated with this load capacitor. The voltage source Vth describes the turn ON threshold voltage of a semiconductor sampling switch 112. During the sample state, the control terminal of sampling switch 112 is coupled with capacitors 158 and 186 and input signal V_{IN} through switch 198.

Once interconnected as described above, the charge stored on the coupled capacitors is redistributed. For example, initially, the charge stored in Cₒ has a substantially zero value, whereas charge on capacitors 158 and 186 is substantially equal to the value given by equation (1). Once interconnected, the voltage on load capacitor Co reaches a value Vo which can be calculated by equation (2) as a function of bias voltage V_{DD} and the number n of bootstrap charge storage devices coupled together.

Vₒ=n*V_{DD}−n(Vₒ−V_{TH})*Co/Cn (2)

Generally speaking, to reduce signal distortions during sampling, it is desirable for the voltage Vₒ representing the sum of the switch threshold voltage and the voltage across capacitors 158 and 186 (the “bootstrap voltage”) to be constant and relatively large to ensure a minimum switch impedance is obtained. However, to maintain an acceptable level of reliability, Vₒ preferably remains below a maximum operating gate voltage of switch 112, to prevent an overdrive condition. In a modern semiconductor process, this voltage is typically within the same order of magnitude as the maximum available power supply voltage.

During the sampling phase, V_{IN} is coupled to capacitors 158 and 186. In a practical implementation, a substantial parasitic capacitance is unavoidably associated with these devices. Thus, coupling the bootstrap capacitors to the input terminal of a sampling system involves the addition of substantial parasitic capacitance to this terminal. Although signal distortions introduced by the sampling switch are reduced through the techniques described herein, additional signal distortions are added by current flowing through the sampling circuit and into the parasitic capacitance associated with the capacitors 158 and 186.

Moreover, the parasitic capacitance present at the input terminal, the sampling capacitor, the sampling circuit input source impedance, and the sampling switch impedance combine to create a higher order network with complex settling characteristics which may result in incomplete settling and undesirable sampling transient behavior.

Because the parasitic capacitance associated with capacitors 158 and 186 is directly proportional with their physical size and thus their capacitance value, it is desirable, to minimize their capacitance value in order to reduce signal distortion imparted as result of capacitive loading at the input.

Considering the charge redistribution relationship described above, the capacitance value of capacitors 158 and 186 C_{EFF} necessary to produce the desired sampling switch control voltage Vₒ during sample state, can be expressed as a function of the sampling switch capacitance Co, the available bias voltage V_{DD} and the sampling switch threshold voltage V_{TH} as shown in equation (3) below.

C_{EFF}=Co*[Vo−V_{TH}]/[V_{DD}−Vo/n] (3)

C_{EFF} may be minimized by increasing or maximizing V_{DD} (i.e., charging capacitors 158 and 186 to the maximum available voltage in hold state) and increasing or maximizing the number of capacitors “n” (i.e. use multiple bootstrap charge storage devices).

It should be noted that in implementations with only one bootstrap capacitor (i.e., when n=1), as Vₒ approaches a maximum acceptable value close to V_{DD}, the value of C_{EFF} increases exponentially. The parasitic capacitance associated with C_{EFF} will thus increase in a similar fashion, rapidly increasing the input source impedance related distortions. It is therefore generally desirable to use a minimum of two “bootstrap” capacitors to charge the control terminal of sampling switch 112. However, persons skilled in the art will recognize that a practical implementation of the bootstrap circuitry described herein includes a complex network of parasitic capacitances associated with all the charge storage devices used, which may limit the benefits of increasing the number of capacitors beyond a certain point.

Thus, as introduced above, the present invention provides improved bootstrap circuitry and techniques for reducing signal distortion in sampling systems. One way in which signal distortion is reduced is by providing a relatively large and substantially constant voltage to a switch control terminal. This is accomplished using multiple energy storage devices which may be charged to voltage V_{DD} during a hold state. When the sampling system transitions to sample state, the energy storage devices may be coupled in series to produce a combined voltage above that required to fully turn ON the sampling switch. However, when this charge is applied to the control terminal of the sampling switch, it is redistributed between all coupled capacitors. This causes the voltage on the storage elements to reach an expected level which is present at the switch control terminal. This expected level is generally the desired turn ON voltage for the sampling switch and is preferably within its safe operating region.

Another way in which signal distortion is reduce is by increasing the hold phase charging bias voltage V_{DD} and by increasing the number of bootstrap capacitors used. These steps enable a decrease of bootstrap capacitors size and, implicitly, a reduction of parasitic loading of the input node during sample phase.

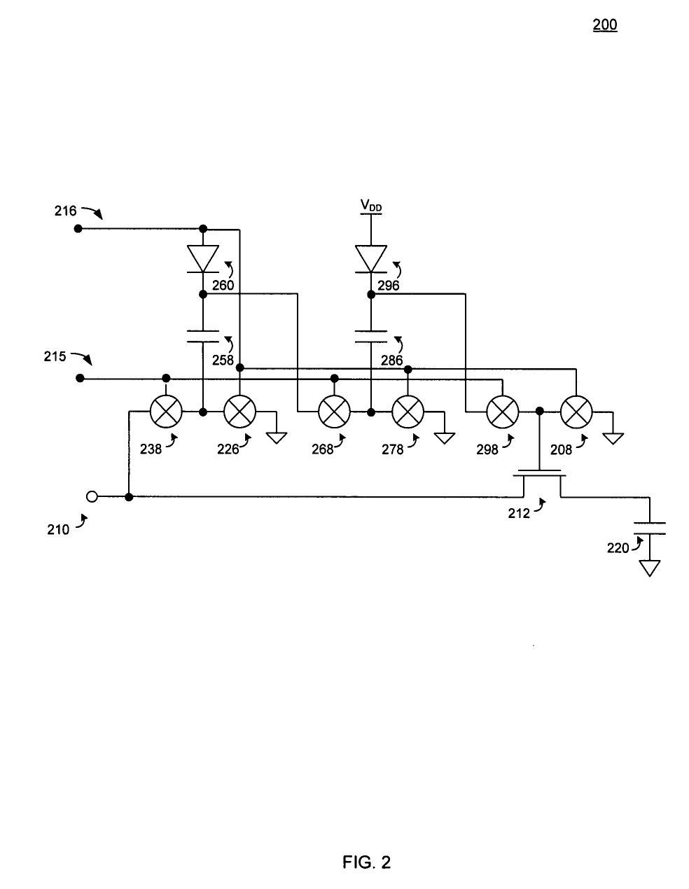

A sampling circuit 200, constructed in accordance with the principles of the present invention, is shown in FIG. 2. The sampling circuit 200 of FIG. 2 generally includes diodes 260 and 296, energy storage components 258 and 286, switches 208, 226, 238, 268, 278 and 298, sampling transistor 212, input node 210, and sampling storage component 220. In this example, storage components 220, 258, and 286 are capacitors or “bootstrap capacitors”, although any other suitable storage component may be used if desired. Moreover, in some embodiments, switches 208, 226, 238, 268, 278 and 298 may be constructed using N-channel MOS transistors, P-channel MOS transistors and CMOS transmission gates, although other suitable semiconductor switches may be used if desired.

The coupling of diode 260 to control line 216 rather than voltage rail V_{DD} reduces the signal distortion associated with diode 260, for example, by reducing the impact of its parasitic capacitance. As FIG. 2 shows, control line 215 is used to control switches 238, 268, and 298 and control line 216 is used to control switches 208, 226, and 278. Sampling switch 212 couples a signal on input node 210 to sampling capacitor 220. Sampling capacitor 220 may be either on or off the chip.

In operation, the impedance of switch 212 may be controlled by switches 208, 238, 268 and 298, and capacitors 258 and 286 depending on the type of control signal applied to control lines 215 and 216. For example, in a sampling state, an ON command (such as a logic high signal) may be applied to control line 215 and an OFF (such as a logic low signal) command may be applied to control line 216, causing switches 238, 268, and 298 to couple capacitors 258 and 286 in series and apply a compound bootstrap voltage to the gate of sampling transistor 212. This turns transistor 212 ON, causing it to conduct and allow the signal at input node 210 to be acquired by sampling capacitor 220. The size of capacitors 258 and 286 may be determined based on the conduction threshold of transistor 212 and/or the value of the available rail voltage(s) to ensure that transistor 212 turns ON to the extent desired (e.g., to ensure a full turn ON with a minimum impedance). In addition, capacitors 258 and 286 are sized relatively small such that, in the sample state, they present a minimum additional load to input node 210.

As mentioned above, in some embodiments, the size of bootstrap capacitors 258 and 286 may be determined based on the turn ON characteristics of switch 212, such that switch 212 is turned on to a desired degree or within certain desired operating parameters. For example, in some embodiments, the value of bootstrap capacitors 258 and 286 may be substantially “matched” with the turn ON voltage of switch 212 such that the charge stored in the capacitors is sufficient to turn switch 212 fully ON (or ON to the degree desired), in view of associated parasitic capacitance, without exposing its control terminal to unnecessary stress associated with excessive voltage. This may involve, for example, providing the substantially minimum voltage required to turn switch 212 fully ON to its control terminal during the sample state. In some embodiments, capacitors 258 and 286 may be of substantially the same value or may be proportioned based on any suitable factor such as circuit layout, device construction and parasitics, etc.

On the other hand, when an ON signal is applied to control line 216 and an OFF command is applied to control line 215 during a hold state, switches 208, 226, and 278 are turned ON. This couples the gate of transistor 212 to ground through transistor 208, turning it OFF, and electrically isolates sampling capacitor 220 from input node 210. This further causes capacitor 258 to be coupled to control line 216 through diode 260, and capacitor 286 to be coupled to voltage source V_{DD} through diode 296, recharging capacitors 258 and 286.

In preferred embodiments, control signals applied to command lines 215 and 216 are inverses of one another such that an ON signal applied to command line 215 causes and OFF signal to be applied to command line 216 and vice versa. During normal operation, this prevents switches 238, 268, and 298 and switches 208, 226, and 278 from being ON simultaneously (e.g., a “break before make” configuration). Specific implementations of circuitry to achieve this condition may include logic gates, flip flops, latches, clocks, or other circuitry to process control signals accordingly.

For example, a control signal may be processed through an inverter, with the input of the inverter applied to control line 215 and the output applied to control line 216 (shown in FIG. 2 as control lines 215 and 316 respectively). It will be understood, however, that circuit 200, and other circuits described herein, may occasionally be placed in special low power modes, in which an “all OFF” condition may be allowed to conserve power. Such a condition may involve removing power or bias signals to some or substantially all components.

In some embodiments, command signals may be provided such that circuit 200 is maintained either in a sample or a hold state and merely toggles between the two. For example, command signals may be either a logic high or logic low signal from an internal or an external source, placing circuit 200 in one of the two modes. This may be done in order to prevent command lines 215 and 216 from “floating” which may place circuit 200 in an indeterminate or undesirable state.

In preferred embodiments, the duration of the sampling period is of sufficient time to allow for settling and ensure proper acquisition of the input signal. In some embodiments, this duration may be dynamic rather than fixed and may vary based on the frequency range of the input signal. However, sampling switch 212 may remain ON as long as the command signal applied to control line 215 directs it to do so. In some embodiments, capacitor 220 may be coupled to ground or other reference, prior to the acquisition of a subsequent input signal, in order to discharge the previously acquired signal. Such embodiments may include the use of additional sampling capacitors and may operate on a “three state” (or more) basis (not shown).

As mentioned above, one benefit of the arrangement shown in FIG. 2 is a reduction in parasitic capacitance associated with diode 260. As shown, this may be achieved by driving the anode of diode 260 from a control signal on command line 216 rather than with rail voltage V_{DD}. Using this arrangement, the control signal applied to command line 216 during a hold state may be configured to have a voltage value approximately equal to V_{DD}, and a voltage value of about zero (e.g., ground) during the sample state.

During a hold state, the anode of diode 260 may be connected to a voltage approximately equal to V_{DD}, which charges capacitor 258 to a value of about V_{DD}−V_{D}. During a subsequent sample state, the anode of diode 260 may be coupled to a voltage approximately equal to zero (e.g., ground), ideally resulting in a reverse diode voltage equal to about −(V_{DD}−V_{D}) even for a minimal, (i.e. zero) input voltage level. This provides a substantial increase in the reverse bias voltage applied across diode 260, reducing its parallel parasitic capacitance and reverse bias leakage current. As a result, charge loss associated with redistribution and reverse leakage current is reduced, which reduces the impedance modulation experienced by switch 212, thereby improving the precision of a sample acquired by capacitor 220. A significant benefit is the reduction in size of capacitors 258 and 286 based on the improved charge retention and consequently a proportional reduction in parasitic loading of input node 210 during the sample state. Nevertheless, during the hold state the capacitors 258 and 286 are charged to a voltage V_{DD}−V_{D} less than the maximum available voltage V_{DD} so, in accordance to the previously described considerations, additional improvements can be made as further described herein.

In some embodiments, the command signal applied to control line 216 may require additional driver or buffer circuitry suitable for providing a voltage approximately equal to V_{DD}. Furthermore, it will be understood that in some embodiments, diode 296 may also be coupled to control line 216 rather than V_{DD} as shown to obtain additional operational benefits similar to or the same as those described above (not shown).

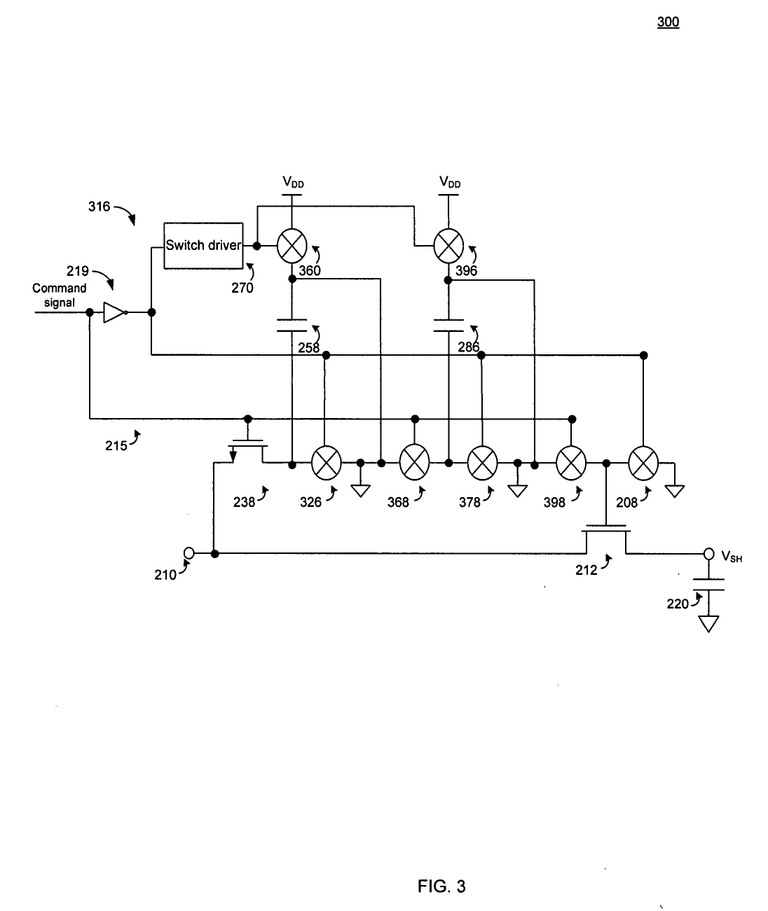

Another circuit constructed in accordance with the principles of the present invention is shown in FIG. 3. Circuit 300 includes several components which may be substantially the same as those in FIG. 2, thus the reference numbers for those components remain the same. The circuit of FIG. 3, however, has been further improved with respect to the circuit of FIG. 2 by the addition of switch driver 270, inverter 219, and the replacement of diodes 260 and 296 with switches 360 and 396.

Circuit 300 may operate substantially similarly to circuit 200, but enjoy further performance benefits from the modifications mentioned above. For example, as shown, diodes 260 and 296 may be replaced by switches 360 and 396, which are controlled by switch driver 270 and coupled to rail voltage V_{DD}. With this configuration, during a hold state, a control signal may be applied to control line 316 through the output of inverter 219 that causes switch driver 270 to turn switches 360 and 396 ON, causing the voltage on capacitors 258 and 286 to be charged to V_{DD}. Switch driver 270 preferably has the capability to drive multiple such switches and may include any suitable circuitry such as a comparator, a boosted clock driver, or other matched or specialized amplifier circuit.

Because diodes 260 and 296 are no longer in the capacitor charging path of circuit 300, the voltage drop associated therewith (V_{D}) is substantially eliminated, enabling the size of capacitors 258 and 286 to be further reduced. Moreover, replacement of the diodes with switches renders the charge on capacitors 258 and 286 substantially independent of input signal variations. This translates into reduced signal distortion in the sampling state because a substantially constant voltage is being applied to the gate of sampling transistor 212 from capacitors 258 and 286, providing a substantially constant switch impedance irrespective of the input signal.

Furthermore, in some embodiments, it may be desirable to implement switch 238 as an NMOS transistor to facilitate transfer of the input signal to the gate of sampling switch 212 for a specified signal range (e.g., if circuit 300 is to be used with input signals substantially within the specified input signal range, an NMOS switch may be used that operates within or is a good match for that range).

It will be understood from the foregoing that in some embodiments of the invention, the component changes described above may occur individually, in certain groups to achieve certain performance benefits, or otherwise. For example, circuit 300 may be constructed such that only diode 260 is replaced with switch 360 with diode 296 remaining. This may be desirable in some instances as the V_{D} of diode 296 has less of an impact on the input signal in the sample state, and therefore, causes less signal distortion on an acquired signal as compared to diode 260. Similarly the parasitic capacitance associated with capacitor 286 has less of an impact upon input node 210. With this configuration, switch driver 270 is coupled to switch 360. Diode 296 and capacitor 286 operate as described above in connection with the circuit of FIG. 2. In other embodiments, diode 260 may be replaced with switch 360 and switch 238 may be an NMOS transistor. Other modifications may be made.

Furthermore, the addition of switch 396 has little impact on the overall size or layout of circuit 300, as switch driver circuit 270 is already present to drive switch 360, but its addition allows for the further size reduction of capacitors 258 and 286.

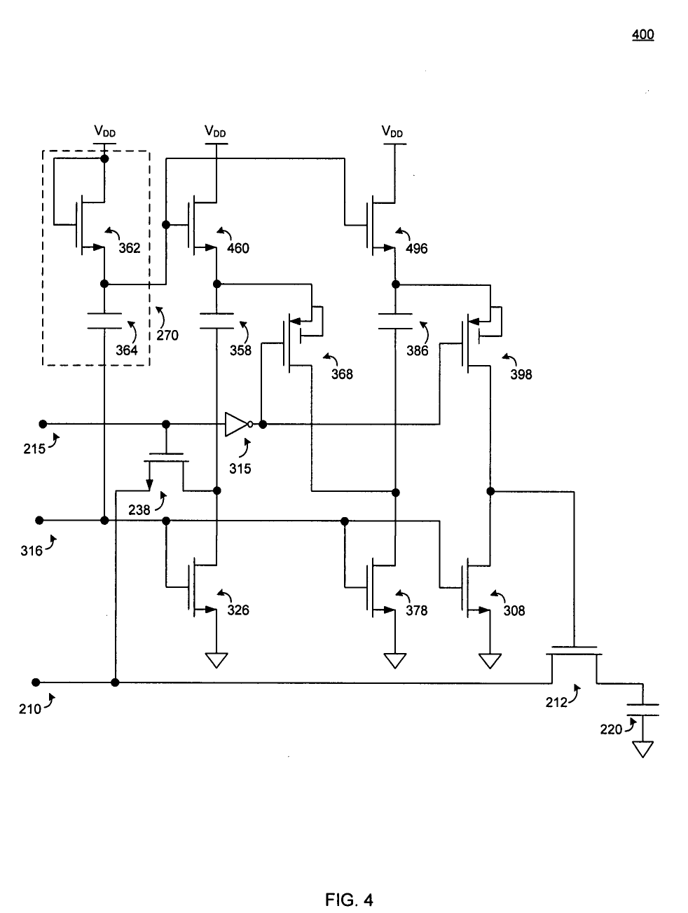

Referring now to FIG. 4, one possible specific implementation 400, constructed in accordance with the principles of the present invention, is shown. Circuit 400 includes several components which may be substantially the same as those in FIG. 3, thus the reference numbers for those components remain the same. Moreover, circuit 400 is similar in certain respects to the circuit described in FIG. 3, and generally includes components and functional blocks which have been numbered similarly to denote similar functionality and general correspondence.

For example, circuit 400 may be constructed using NMOS transistors 308, 326, 378, 460, and 496 (switches 208, 326, 378, 360 and 396 in FIG. 3), and PMOS transistors 368 and 398 (switches 368 and 398 in FIG. 3). Switch driver 270 may be constructed using a known clock-boosting driver circuit with NMOS transistor 362 and capacitor 364 or any other suitable circuit.

In operation, command signals applied to control line 316 control the operation of NMOS transistors 326, 378, and 308. In addition, signals on control line 316 also control the operation of NMOS devices 460 and 496 through switch driver 270. During a hold state, a logic high signal may be applied to control line 316 which turns ON transistors 308, 326, 378, 460, and 496 such that they provide a low impedance path between their respective source and drain terminals. This causes capacitors 358 and 386 to be charged to a voltage approximately equal to V_{DD} through the conduction path established by NMOS transistors 460 and 496.

As mentioned above, during a hold state, the gate of sampling switch 212 is preferably coupled to ground (or other OFF signal) thereby maintaining a high impedance between its source and drain terminals such that sampling capacitor 220 is electrically isolated from input node 210. This may be achieved by concurrently applying an OFF signal to the gate of PMOS transistor 398 and an ON signal to the gate of NMOS transistor 308. Capacitors 358 and 386 are isolated from each other and from the input node 210 by applying OFF signals to the gate of PMOS transistor 368 and NMOS transistor 238.

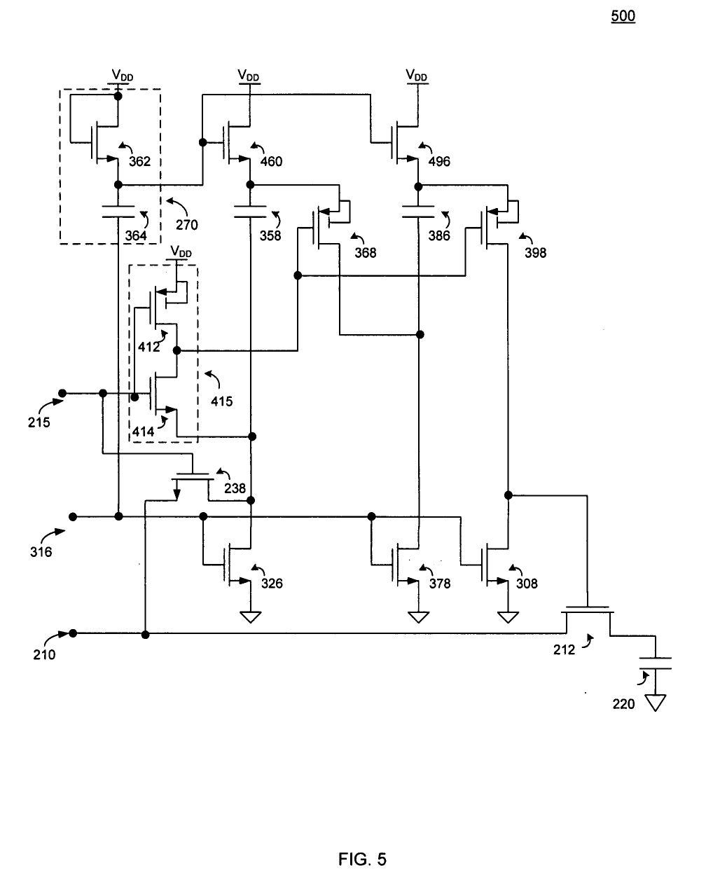

In some embodiments, the value of rail voltage V_{DD} may be high enough that it forces PMOS transistors 368 and 398 to function beyond their safe operating region during a sampling state. In this case, it may be desirable to limit the gate-to-source voltage applied to these PMOS transistors so they remain within normal operating parameters. This may be accomplished by using a limiting circuit, which may be implemented by replacing the ground-referenced inverter 315 with an input-signal-referenced inverter circuit 415 (shown in FIG. 5).

In some embodiments as shown in FIG. 3, only one logic signal is needed to toggle circuit 400 between sample and hold states. For example, as shown in FIG. 3, FIG. 4 can be modified so that a logic low signal can be applied to control the common control node 215, from which the logic signal 316 can be obtained via inversion. In that case, transistors 308, 326, 378, 460 and 496 are ON, and transistors 238, 368 and 398 are OFF placing circuit 400 in a hold state. If a logic high signal is applied to the common control node 215, therefore applying a logic low to control line 316, the opposite is true, placing circuit 400 in a sample mode. This configuration may be desirable in embodiments where it is desired to reduce the number or complexity of control signals needed to operate circuit 400.

When transitioning from a hold state to a sample state, a logic high command signal may be applied to control line 215 and a logic low to control line 316, which turns PMOS transistors 368 and 398, and NMOS transistor 238 ON (through inverter 315) such that they provide a low impedance path between their respective source and drain terminals. Simultaneously, transistors 308, 326, 378, 460 and 496 are turned OFF. Thus, capacitors 358 and 386 are connected in series and coupled between the source and gate terminals of the sampling switch 212, and their combined voltage causes the switch to turn ON. This provides a low and substantially constant impedance between its source and drain terminals, allowing circuit 400 to acquire a precision sample of the input signal at sampling capacitor 220.

In some embodiments, the input signal range may be such that during the sample state, NMOS transistor 238 can not be adequately turned ON by a control signal applied to node 215 even when this signal is substantially equal with power supply voltage V_{DD} and the use of a boosted control signal (as subsequently shown in circuit 600) is not desirable. In this case the NMOS transistor 238 may be replaced by a CMOS transmission gate (not shown).

As in the circuits of FIGS. 2 and 3, capacitors 358 and 386 are sized relatively small such that, when coupled to input node 210 during sample state they introduce a reduced additional input parasitic capacitance. When transitioning from a hold state to a sample state, the charge between the electrodes of capacitor 358 and the charge between the electrodes of capacitor 386 are redistributed. As a result, the voltage on the capacitors is not maintained constant when transitioning from the hold state to the sample state but instead drops to a desired value during the sample state to prevent switch 212 from being over-driven while presenting a low sampling impedance, substantially independent of input signal value.

As shown, circuit 500 of FIG. 5 is substantially the same as circuit 400 of FIG. 4. However, in circuit 500, inverter 315 has been replaced with a driver circuit 415 constructed using PMOS transistor 412 and NMOS transistor 414 which references the input signal rather than ground. The gate of each transistor is coupled connected to control line 215. Thus, when a logic low or hold command is applied to control line 215, NMOS transistors 238 and 414 are OFF, whereas PMOS transistor 412 is ON, providing a voltage approximately equal to V_{DD} to the gate of transistors 368 and 398, turning them OFF.

During a sampling state however, the control signal is toggled, and a sample command is applied to control line 215 approximately equal to rail voltage V_{DD}. This turns PMOS transistor 412 OFF, and NMOS transistors 238 and 414 ON. As a consequence, PMOS transistors 368 and 398 are turned ON and the series combination of capacitors 358 and 386 are coupled in series as shown in FIG. 4. In this way, the drive signal from inverter 415 is referenced to the input signal during the sampling state through NMOS transistor 238, thus limiting the gate-to-source voltage applied to PMOS transistors 368 and 398.

In some embodiments, the range of the input signal at input node 210 may be comparable to the value of rail voltage V_{DD}. In this case, the magnitude of the standard, i.e. non-boosted turn ON signal provided to control line 215 may be inadequate to turn NMOS transistor 238 ON to an extent that can accommodate such an input signal. The result may be an under-driven sampling transistor 212, which distorts signals acquired during the sampling state.

Accordingly, it may be desirable to boost the value of the signal used to drive NMOS transistors 238 and 414. One way which this may be accomplished is to replace NMOS transistors 238 and 414 with CMOS transmission gates (not shown). In certain implementations, however, this solution may be undesirable due to the variation of the CMOS transmission gate impedance with input signal. An alternative solution can be achieved by adding additional driver circuitry that boosts the value of the control signals of the circuit in FIG. 5.

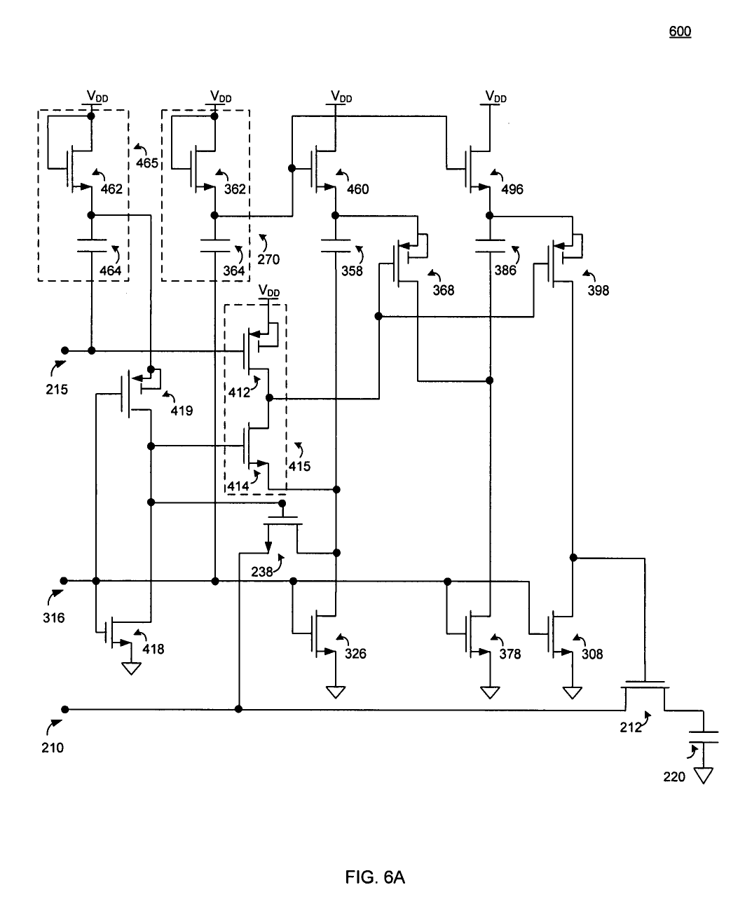

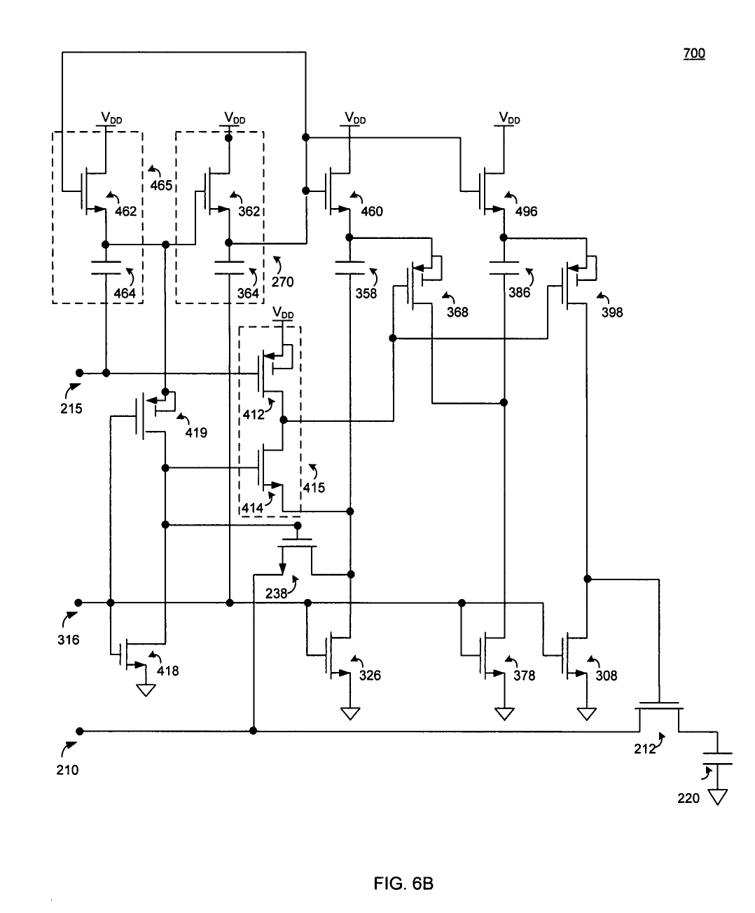

Specific implementations of such circuits are shown in FIG. 6A as circuit 600 and in FIG. 6B as circuit 700. As shown, circuit 600 is substantially the same as circuit 500 of FIG. 5. However, in circuit 600, a switch driver circuit 465 has been added which boosts the drive signal applied via the control line 215. Switch driver circuit 465 may be implemented as a boosted clock driver circuit using NMOS transistor 462 and capacitor 464, although any other suitable switch driver circuit may be used if desired.

In operation, a control signal applied at control line 215 is increased by a value of about V_{DD} minus the voltage drop across NMOS transistor 462 (in diode-connected configuration). The result is an increased drive signal applied to the gates of transistors 238 and 414, which allows circuit 600 to accept input signals having a magnitude comparable with V_{DD} and still provide a substantially constant impedance at sampling switch 212, allowing high precision sample acquisition of input signals with a relatively large amplitude.

Because the voltage on capacitor 464 is clamped to a minimum of about V_{DD} minus the voltage drop across NMOS transistor 462, the level of the signal on control line 215 does not return to ground when a logic low signal is applied. Thus, to ensure that transistors 238 and 414 turn OFF when a hold state is desired, interface circuitry including NMOS transistor 418 and PMOS transistor 419 may be added and coupled to control line 316. These transistors may act as a gating stage to ensure that NMOS transistors 414 and 238 turn fully OFF during a hold state.

The embodiments shown in FIGS. 6A and 6B employ two separate and independent voltage boosting circuits such as switch drivers 465 and 270. An alternate embodiment that may be used to increase the range of input signals that can be accepted by the circuit of FIG. 5 is illustrated in FIG. 6B. As shown, circuit 700 includes a cross-coupled booster configuration that couples switch drivers 465 and 270. More specifically, the gate of transistor 462 is coupled to the source of transistor 362 (and vice versa) and also to the gate of transistors 460 and 496. With this arrangement, switch drivers 465 and 270 may actively and reciprocally drive each other and are synchronized with the complementary states of control signal 215. Switch driver 465 drives transistors 238 and 414 (through the intermediate gating stage), whereas circuit 270 drives transistors 460 and 496.

The use of switches rather than diodes in the booster circuits described above develops a higher overdrive voltage for internal switching and provides a higher reverse shut-off voltage to transistors 460 and 496 during the sample phase, thus allowing for larger input signals and common mode voltages that minimize or eliminate distortion effects associated with “soft turn-off”.

An alternate embodiment that may be used to increase the range of input signals that can be accepted by the circuit of FIG. 4 includes a configuration that drives transistor 238 from the bootstrapped voltage used to drive sampling transistor 212.

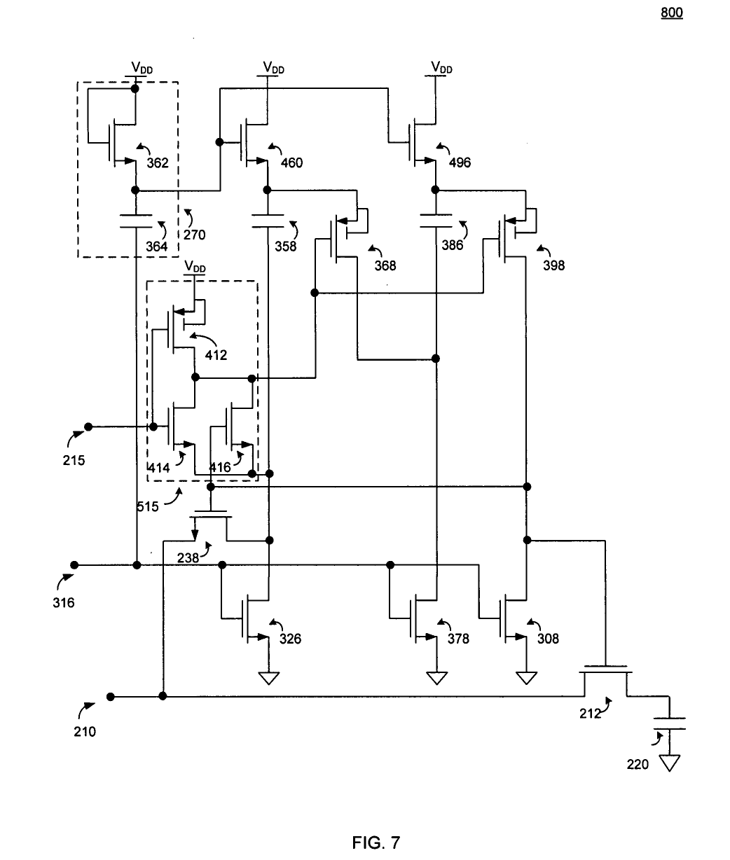

A specific implementation of such a circuit is shown as circuit 800 in FIG. 7. As shown, circuit 800 is substantially the same as circuit 500 of FIG. 5. However, in circuit 800, inverter 315 has been replaced with an inverter circuit 515 constructed using parallel connected NMOS transistors 414 and 416, and PMOS transistor 412. As shown, the gate of each of transistors 238 and 416 are coupled to the gate of transistor 212. Thus, when a logic low or hold command is applied to control line 215, NMOS transistor 414 (and 416 also, shut down by NMOS 308) are OFF, whereas PMOS transistor 412 is ON, providing a voltage approximately equal to V_{DD} to the gate of PMOS transistors 368 and 398, turning them OFF, which turns OFF transistor 238.

During a transition to a sampling state however, the control signal is toggled, and a sample command is applied to control line 215 approximately equal to rail voltage V_{DD}. This turns PMOS transistor 412 OFF, and NMOS transistor 414 ON. As a consequence, the gates of PMOS transistors 368 and 398 are pulled down, turning these devices ON. Thus the series combination of capacitors 358 and 386 causes a rapid increase of the voltage driving the gates of transistors 238 and 416, causing them to turn ON. Subsequently, depending upon the input signal voltage level, the impedance between the source and drain terminals of transistor 414 may increase, tending to turn transistor 414 OFF. This, however, does not have a significant effect on the gate voltage of transistor 212 as transistor 416 is unaffected by the operation of transistor 414 and remains ON.

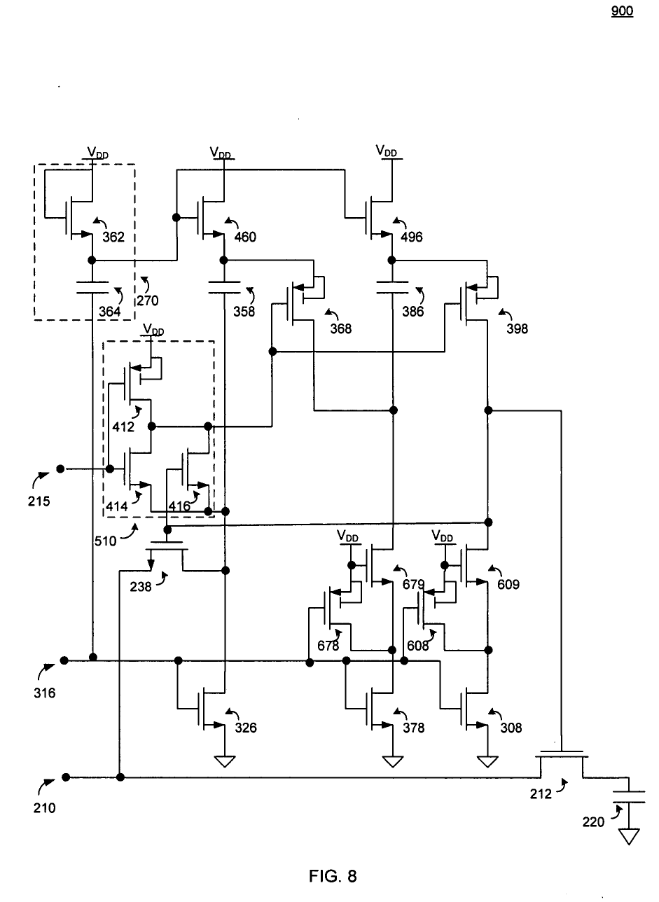

In some embodiments, the value of rail voltage V_{DD} may be high enough that it forces NMOS transistors 308 and 378 to function beyond their safe operating region during a sampling state (e.g., approaching breakdown). In this case, it may be desirable to limit the source-to-drain voltage applied to these NMOS transistors so they remain within normal operating boundaries. As shown in FIG. 8, one way this may be accomplished is by adding NMOS transistors 609 and 679 having rail voltage V_{DD} applied to their gate terminals.

When a logic high or hold command is applied to control line 316, PMOS transistors 678 and 608 are OFF, whereas NMOS transistors 378 and 308 are ON, turning NMOS transistors 609 and 679 ON also. This allows capacitor 386 to charge to a voltage approximately equal to V_{DD} and the gate of sampling transistor 212 is coupled to ground.

During a sampling state however, the control signal is toggled, and a sample command is applied to control line 316 approximately equal to ground. This turns PMOS transistors 608 and 678 ON, and NMOS transistors 308 and 378 OFF. As a consequence, NMOS transistors 609 and 679 are turned OFF. With this configuration, the voltage applied to NMOS transistors 308 and 378 is limited to V_{DD} in sample mode, and does not exceed the rail voltage V_{DD} minus the gate-to-source voltage drop across NMOS transistors 609 and 679 in hold mode. In some embodiments, it may be desirable to arrange additional NMOS transistors in series with NMOS transistors 609 and 679 to further reduce the source-to-drain voltage applied to transistors 308 and 378.

Although preferred embodiments of the present invention have been disclosed with various circuits coupled to other circuits, persons skilled in the art will appreciate that it may not be necessary for such couplings to be direct and additional circuits may be coupled in between the shown connected circuits without departing from the spirit of the invention as shown. Persons skilled in the art also will appreciate that the present invention can be practiced by other than the specifically described embodiments. The described embodiments are presented for purposes of illustration and not of limitation, and the present invention is limited only by the claims which follow.

What is claimed is:

1. A sample circuit that operates in at least a sample state and a hold state, the sample circuit comprising:
an input terminal coupled to a sample capacitor through a semiconductor sampling switch for selectively receiving an input signal;
a plurality of charge storage devices coupled to a bias voltage during the hold state and selected to reduce input terminal loading during the sample state;
the plurality of charge storage devices being coupled to a control terminal of the semiconductor sampling switch during the sample state such that charge stored on the plurality of charge storage devices is superimposed on the input signal and applied to the control terminal of the semiconductor sampling switch such that the semiconductor sampling switch remains within a safe operating region and has a low and substantially constant input impedance during the sample state.

2. The sample circuit of claim 1 wherein input impedance of the semiconductor sampling switch is substantially independent of input terminal voltage.

3. The sample circuit of claim 1 wherein the plurality of charge storage devices are coupled in series during the sample state.

4. The sample circuit of claim 1 wherein a value of the plurality of charge storage devices is selected to minimize capacitive loading on input terminal.

5. The sample circuit of claim 1 further comprising proportioning a value of the plurality of charge storage devices such that charge stored on the plurality of charge storage devices is sufficient to substantially compensate for parasitic capacitance associated with the control terminal of the semiconductor sampling switch.

6. The sample circuit of claim 1 further comprising proportioning a value of the plurality of charge storage devices such that charge stored on the plurality of charge storage devices substantially matches a minimum voltage required to set the impedance of the semiconductor sampling switch to a substantially constant minimum value during the sample state.

7. The sample circuit of claim 1 wherein the plurality of charge storage devices are capacitors and wherein a higher value of the bias voltage allows a capacitance of the plurality of capacitors to be lower.

8. The sample circuit of claim 7 wherein capacitive loading on the input terminal is reduced as the bias voltage increases and the capacitance of the plurality of capacitors is decreased.

9. The sample circuit of claim 1 wherein the plurality of charge storage devices are capacitors and wherein capacitive loading on the input terminal is reduced as a number of capacitors in the plurality of capacitors is increased.

10. The sample circuit of claim 1 wherein the plurality of charge storage devices are coupled substantially directly to the bias voltage during the hold state.

11. The sample circuit of claim 1 wherein at least one of the plurality of charge storage devices is coupled to a control terminal through a diode, the control terminal providing a control voltage that charges the at least one charge storage device during the hold state and provides a voltage sufficient to substantially turn OFF the diode during a sample state.

12. The sample circuit of claim 1 wherein the voltage of the plurality of charge storage devices decreases during the sample state.

13. A method of acquiring a sampled signal in a sample circuit that reduces signal distortion on the acquired signal and that operates in at least a sample state and a hold state, the method comprising:
coupling a semiconductor sampling switch between an input terminal and a sample capacitor for selectively receiving an input signal;
selecting a plurality of charge storage devices to reduce input terminal loading during the sample state;
coupling the plurality of charge storage devices to a bias voltage during the hold state; and
coupling the plurality of charge storage devices to a control terminal of the semiconductor sampling switch during the sample state such that charge stored on the plurality of charge storage devices is superimposed on the input signal and applied to the control terminal of the semiconductor sampling switch such that the semiconductor sampling switch remains within a safe operating region and has a low and substantially constant input impedance during the sample state

14. The method of claim 13 wherein impedance of the semiconductor sample switch is substantially independent of input terminal voltage.

15. The method of claim 13 further comprising coupling the plurality of charge storage devices in series during the sample state.

16. The sample circuit of claim 13 wherein a value of the plurality of charge storage devices is selected to minimize capacitive loading on input terminal

17. The method of claim 13 further comprising proportioning a value of the plurality of charge storage devices such that charge stored on the plurality of charge storage devices is sufficient to substantially compensate for parasitic capacitance associated with the control terminal of the semiconductor sample switch.

18. The method of claim 13 further comprising proportioning a value of the plurality of charge storage devices such that charge stored on the plurality of charge storage devices substantially matches a minimum voltage required to set the impedance of the semiconductor switch to a substantially constant minimum value during the sample state.

19. The method of claim 13 wherein the plurality of charge storage devices are capacitors and wherein a higher value of the bias voltage allows a capacitance of the plurality of capacitors to be lower.

20. The method of claim 19 wherein capacitive loading on the input terminal is reduced as the bias voltage increases and the capacitance of the plurality of capacitors is decreased.

21. The method of claim 13 wherein the plurality of charge storage devices are capacitors and wherein capacitive loading on the input terminal is reduced as a number of capacitors in the plurality of capacitors is increased.

22. The method of claim 13 further comprising coupling the plurality of charge storage devices substantially directly to the bias voltage during the hold state.

23. The method of claim 13 wherein at least one of the plurality of charge storage devices is coupled to a control terminal through a diode, the control terminal providing a control voltage that charges the at least one charge storage device during the hold state and provides a voltage sufficient to substantially turn OFF the diode during a sample state.

24. The method of claim 13 wherein the voltage of the plurality of charge storage devices decreases during the sample state.
